(19) United States
(12) Patent Application Publication
(10) Pub. No.: US 2025/0053200 A1
(43) Pub. Date: Feb. 13, 2025

(54) WINDOW AND DISPLAY DEVICE INCLUDING THE SAME

(71) Applicant: Samsung Display Co., LTD., Yongin-si (KR)

(72) Inventor: SU-HYOUNG KANG, Yongin-si (KR)

(21) Appl. No.: 18/790,682

(22) Filed: Jul. 31, 2024

(30) Foreign Application Priority Data
Aug. 8, 2023 (KR) 10-2023-0103609

(51) Int. Cl. G06F 1/16; G02B 1/115; G02B 1/14

(52) U.S. Cl. CPC G06F 1/1656; G02B 1/115; G02B 1/14; G06F 1/1616

(57) ABSTRACT

Provided is a window and a display device including the same. The window includes: a hard coating layer including a polymer derived from a resin composition including a photoinitiator, a fluorine-based compound, an acrylate-based compound, and a reactive diluent, and the acrylate-based compound includes at least one of polyester acrylate, epoxy acrylate, urethane acrylate, or ethylene glycol acrylate. The reactive diluent includes at least one of polyester acrylate or polyether acrylate having a molecular weight of greater than 0 grams per mole (g/mol) and about 1000 grams per mole (g/mol) or less.

This application claims priority to Korean Patent Application No. 10-2023-0103609, filed on Aug. 8, 2023, and all the benefits accruing therefrom under 35 U.S.C. § 119, the content of which in its entirety is herein incorporated by reference.

### BACKGROUND

The present disclosure herein relates to a window and a display device including the same, and more particularly, to a window with an excellent folding property and durability and a display device including the same.

Various shapes of electronic devices are used to provide image information. The electronic devices, including a flexible display device which is foldable or bendable, are being developed. Unlike a rigid display device, the flexible display device is foldable, rollable, bendable, and/or the like, that is, deformable into various shapes, and thus has a property of being portable regardless of a display screen size.

It is desirable for such a flexible display device to have a window for protecting a display panel without causing deterioration in a folding or bending operation. Therefore, it is desirable to develop a window having not only an excellent optical property and mechanical property, but also an excellent folding property.

### SUMMARY

The present disclosure provides a window which has an improved impact resistance and an excellent folding property and is thus capable of preventing an occurrence of cracks.

The present disclosure also provides a display device with an excellent durability even in a low curvature structure by including a window having an improved impact resistance and folding property.

An embodiment of the invention provides a window including: a hard coating layer including a polymer derived from a resin composition including a photoinitiator, a fluorine-based compound, an acrylate-based compound, and a reactive diluent. The acrylate-based compound includes at least one of polyester acrylate, epoxy acrylate, urethane acrylate, or ethylene glycol acrylate, and the reactive diluent includes at least one of polyester acrylate or polyether acrylate having a molecular weight of greater than 0 and about 1000 grams per mole (g/mol) or less.

In an embodiment, the resin composition may further include an ultraviolet absorber, and the ultraviolet absorber may include at least one of a salicylic acid-based compound, a benzophenone-based compound, a benzotriazole-based compound, a cyanoacrylate-based compound, a nickel phenolate-based compound, or a hindered amine-based compound.

In an embodiment, the ultraviolet absorber may include at least one of 2-(2-hydroxy-5-methylphenyl)benzotriazole, 2-(3-ter-butyl-2-hydroxy-5-methylphenyl)-2H-5-chlorobenzotriazole, 2-(2′-hydroxy-5′-ter-octylphenyl)benzotriazole, or 2-hydroxy-4-n-octoxybenzophenone.

In an embodiment, the window may further include an adhesive layer disposed below the hard coating layer; and a primer layer disposed between the adhesive layer and the hard coating layer. The primer layer may include a silicon oxide and an ultraviolet absorber, and the ultraviolet absorber may include at least one of a salicylic acid-based compound, a benzophenone-based compound, a benzotriazole-based compound, a cyanoacrylate-based compound, a nickel phenolate-based compound, or a hindered amine-based compound.

In an embodiment, the photoinitiator may include at least one of an acetophenone-based compound, a sulfonium-based compound, or a benzophenone-based compound.

In an embodiment, the fluorine-based compound may include perfluoropolyether.

In an embodiment, the resin composition further may further include an additive represented by the following Chemical Formula 1 or Chemical Formula 2:

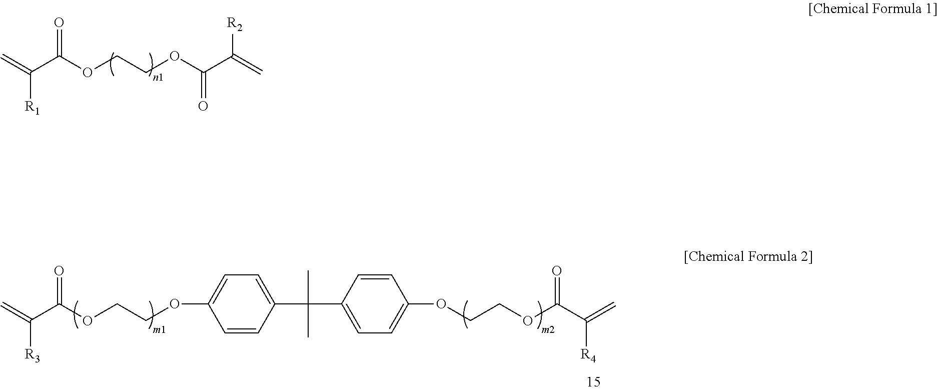

in Chemical Formula 1 and Chemical Formula 2, R1 to R4 is each independently a hydrogen atom or an unsubstituted methyl group, n1 is an integer of 1 to 10, m1 and m2 are each independently an integer of 1 to 20, and a sum of m1 and m2 is 10 to 30.

In an embodiment, the acrylate-based compound may further include alkyl(meth)acrylate.

In an embodiment, the window may further include a high refractive layer disposed on the hard coating layer and having a first refractive index of about 1.6 or more; and a low refractive layer disposed on the high refractive layer and having a second refractive index of about 1.5 or less.

In an embodiment, the high refractive layer may include at least one of tin oxide (SnOₓ), titanium oxide (TiOₓ), zirconium oxide (ZrOₓ), or a sulfur atom. In an embodiment, the low refractive layer may include a hollow particles having an average diameter of about 30 nanometers (nm) to about 70 nm.

In an embodiment, the window may further include a functional layer disposed on the low refractive layer and including a fluorine-containing compound.

In an embodiment, the hard coating layer may have a thickness of about micrometers (μm) to about 100 μm.

In an embodiment of the invention, a display device includes: a display panel; and a window disposed on the display panel. The window includes a hard coating layer including a polymer derived from a resin composition including a photoinitiator, a fluorine-based compound, an acrylate-based compound, and a reactive diluent, the acrylate-based compound includes at least one of polyester acrylate, epoxy acrylate, urethane acrylate, or ethylene glycol acrylate, and the reactive diluent includes at least one of polyester acrylate or polyether acrylate having a molecular weight of greater than 0 and about 1000 g/mol or less.

In an embodiment of the invention, a display device includes: a display module including a first non-folding region, a folding region, and a second non-folding region, which are disposed along a first direction; and a window disposed on the display module. The window includes an adhesive layer directly disposed on the display module, and a hard coating layer disposed on the adhesive layer and including a polymer derived from a resin composition including a photoinitiator, a fluorine-based compound, an acrylate-based compound, a reactive diluent, and an ultraviolet absorber. The reactive diluent includes at least one of polyester acrylate or polyether acrylate having a molecular weight of about 1000 g/mol or less.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is a perspective view illustrating an unfolded state of a display device according to an embodiment of the invention;

FIG. 1B is a perspective view illustrating that a display device according to an embodiment of the invention is being in-folded;

FIG. 1C is a perspective view illustrating that a display device according to an embodiment of the invention is being out-folded;

FIG. 2A is a perspective view illustrating an unfolded state of a display device according to another embodiment of the invention;

FIG. 2B is a perspective view illustrating that the display device, according to an embodiment of the invention, illustrated in FIG. 2A is being in-folded;

FIG. 3 is a perspective view of a display device according to still another embodiment of the invention;

FIG. 4 is an exploded perspective view of a display device according to an embodiment of the invention;

FIG. 5 is a cross-sectional view of a display device according to an embodiment of the invention;

FIG. 6 is an exploded perspective view of a display device according to another embodiment of the invention;

FIG. 7 is a cross-sectional view of a display device according to an embodiment of the invention;

FIGS. 8 to 11 are cross-sectional views of a window according to embodiments of the invention, respectively; and

FIG. 12 is a graph showing a light transmittance of a window according to embodiments of the invention.

### DETAILED DESCRIPTION

The invention may be implemented in various modifications and have various forms, and specific embodiments are illustrated in the drawings and described in detail in the text. It is to be understood, however, that the invention is not intended to be limited to the particular forms disclosed, but on the contrary, is intended to cover all modifications, equivalents, and alternatives falling within the spirit and scope of the invention.

In this specification, the singular forms include the plural forms as well, unless the context clearly indicates otherwise.

In this specification, it will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

In this specification, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

In this specification, “being disposed on” may mean to be disposed not only on an upper part but also on a lower part of one member.

In this specification, it will be understood that “being directly disposed” means that there are no intervening layers, films, regions, plates, or the like between a portion of layers, films, regions, plates, or the like and another portion. For example, “being directly disposed” may mean to be disposed between two layers or two members without using an additional member such as an adhesive member or like.

In this specification, the term “and/or” includes all combinations of one or more of the associated listed elements.

In this specification, although the terms “first”, “second”, etc., may be used to describe various elements, these elements should not be limited by these terms. These terms are only used to distinguish one element from another element. For example, a first element may be referred to as a second element, and similarly, a second element may also be referred to as a first element without departing from the scope of the invention.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Like reference numerals or symbols refer to like elements throughout. Also, in the drawings, the thickness, the ratio, and the dimension of the elements are exaggerated for effective description of the technical contents.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10%, 5% or 2% of the stated value. Hereinafter, a window according to an embodiment of the invention and a display device including the same will be described with reference to the accompanying drawings.

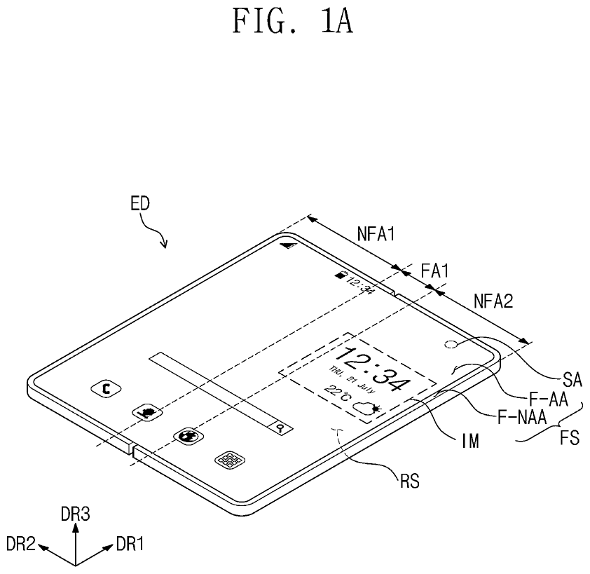

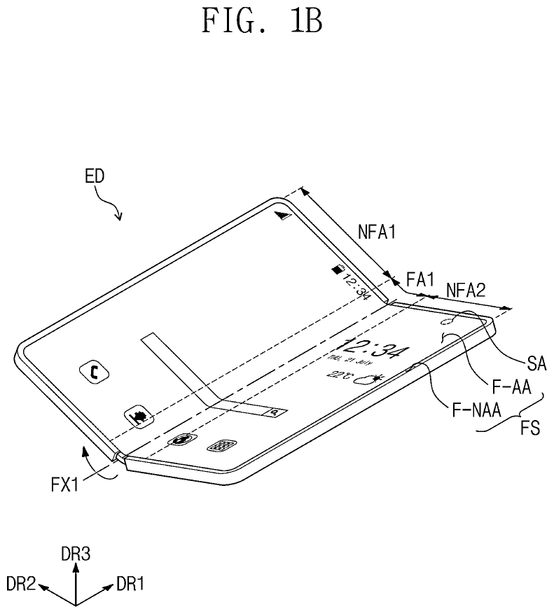

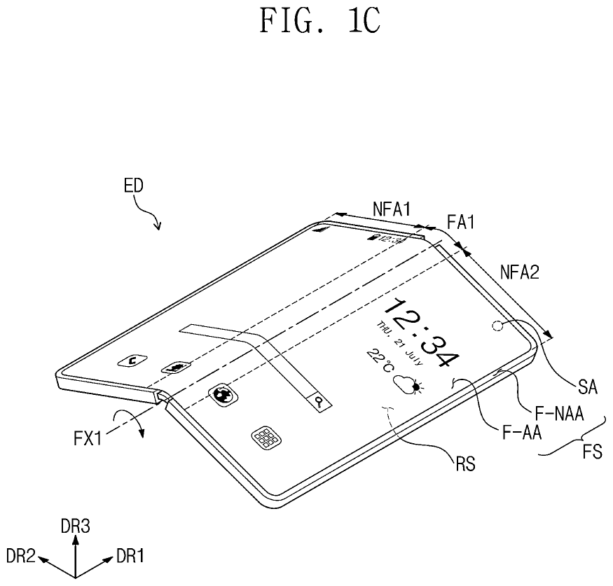

FIGS. 1A to 1C, 2A, 2B, and 3 are perspective views illustrating a display device according to embodiments, respectively. FIG. 1A is a perspective view illustrating an unfolded state of a display device according to an embodiment of the invention. FIG. 1B is a perspective view illustrating that the display device illustrated in FIG. 1A is being in-folded. FIG. 1C is a perspective view illustrating that a display device ED illustrated in FIG. 1A is being out-folded.

The display device ED according to an embodiment may be activated in response to an electrical signal. For example, the display device ED may be a mobile phone, a tablet computer, a car navigation system, a game console, or a wearable device, but an embodiment of the invention is not limited thereto. In FIGS. 1A to 1C, etc., the display device ED is exemplarily illustrated as a mobile phone.

In FIG. 1A and the following drawings, a first direction DR1, a second direction DR2, and a third direction DR3 are illustrated, and directions indicated by the first to third directions DR1 to DR3 described herein may have a relative concept and thus may be changed to other directions.

Referring to FIGS. 1A to 1C, the display device ED according to an embodiment may include a display surface FS defined by the first direction DR1 and the second direction DR2 crossing the first direction DR1. The display device ED may display an image IM through the display surface FS. The display device ED according to an embodiment may display, in the third direction DR3, the image IM on the display surface FS parallel to each of the first direction DR1 and the second direction DR2. In FIGS. 1A to 1C, a clock image and application icons are exemplarily illustrated as the image IM. In this specification, “a display surface” may be referred to as “a first display surface”, and the same reference numeral or symbol may be used for the display surface and the first display surface.

In this specification, a front surface (or upper surface) and a rear surface (or lower surface) of each of components are defined based on a direction in which the image IM is displayed. In FIG. 1A and the following drawings, a front surface (or upper surface) and a rear surface (or lower surface) of each of members configuring display devices ED, ED-a, and ED-b may be opposed to each other in the third direction DR3, and the normal direction of each of the front surface and the rear surface may be parallel to the third direction DR3. A spacing distance between the front surface and the rear surface defined along the third direction DR3 may correspond to a thickness of a member (or unit). In this specification, the wording “on a plane” may be defined as a state when viewed in the third direction DR3 (in other word, “in a plan view”). In this specification, the wording “on a cross section” may be defined as a state when viewed in the first direction DR1 or the second direction DR2 (in other word, “in a cross-sectional view”). The display device ED according to an embodiment may detect an external input applied from the outside. The external input may include various types of inputs applied from the outside of the display device ED. In an embodiment, for example, the external input may include not only a touch by a part of a user's body such as user's hands but also an external input (for example, hovering) applied while approaching or being adjacent within a predetermined distance to the display device ED. Additionally, the external input may have various forms such as force, pressure, temperature, light, and the like.

The display surface FS of the display device ED may include an active region F-AA and a peripheral region F-NAA. The active region F-AA may be activated in response to an electrical signal. The display device ED according to an embodiment may display the image IM through the active region F-AA. Also, various types of external inputs may be detected in the active region F-AA. The peripheral region F-NAA may be adjacent to the active region F-AA. The peripheral region F-NAA may have a predetermined color. The peripheral region F-NAA may surround the active region F-AA. Accordingly, a shape of the active region F-AA may be substantially defined by the peripheral region F-NAA. However, this is exemplarily illustrated. The peripheral region F-NAA may be disposed to be adjacent to only one side of the active region F-AA or may be omitted. The display device ED according to an embodiment of the invention may include an active region having various shapes, but is not limited to any one embodiment.

A sensing region SA may be included in the active region F-AA. Various electronic modules may be disposed in the sensing region SA. In an embodiment, for example, the electronic module may include at least one of a camera module, a speaker, a light detection sensor, or a heat detection sensor. The sensing region SA may detect an external subject received through the display surface FS or provide a sound signal such as voice to the outside through the display surface FS. The electronic module may include a plurality of components, and is not limited to any one embodiment.

The sensing region SA may be surrounded by the active region F-AA and the peripheral region F-NAA. However, an embodiment of the invention is not limited thereto. In another embodiment, the sensing region SA may be disposed inside the active region F-AA, and is not limited to any one embodiment. FIG. 1A, etc., exemplarily illustrate one sensing region SA, but the number of the sensing regions SA is not limited thereto.

The sensing region SA may be a portion of the active region F-AA. Therefore, the display device ED may also display an image even in the sensing region SA. When the electronic modules disposed in the sensing region SA are deactivated, the sensing region SA may serve as a display surface capable of display a video or image.

A rear surface RS of the display device ED according to an embodiment may be a surface facing the display surface FS. In an embodiment, the rear surface RS is an outer surface of the display device ED, and a video or image may not be displayed thereon. However, an embodiment of the invention is not limited thereto, and the rear surface RS may serve as a second display surface on which a video or image is displayed in another embodiment. Also, the display device ED according to an embodiment may further include a sensing region disposed in the rear surface RS. A camera, a speaker, a light detection sensor, etc., may also be disposed in the sensing region disposed in the rear surface RS.

The display device ED may include a folding region FA1 and non-folding regions NFA1 and NFA2. The display device ED may include a plurality of non-folding regions NFA1 and NFA2. The display device ED according to an embodiment may include a first non-folding region NFA1 and a second non-folding region NFA2 disposed with the folding region FA1 therebetween. FIGS. 1A to 1C illustrate embodiments of the display device ED including one folding region FA1, but an embodiment of the invention is not limited thereto. A plurality of folding regions may be defined in the display device ED in another embodiment. The display device ED according to an embodiment may be folded with respect to a plurality of folding axes, and may be folded so that portions of the display surface FS face each other. The number of folding axes and the number of non-folding regions corresponding thereto are not particularly limited.

Referring to FIGS. 1B and 1C, the display device ED according to an embodiment may be folded with respect to a first folding axis FX1. The first folding axis FX1 illustrated in FIGS. 1B and 1C may be an imaginary axis extending in the first direction DR1 and be parallel to a long-side direction of the display device ED. However, an embodiment of the invention is not limited thereto, and an extending direction of the first folding axis FX1 is not limited to the first direction DR1.

The first folding axis FX1 may extend, on the display surface FS, along the first direction DR1 or extend, below the rear surface RS, along the first direction DR1. Referring to FIG. 1B, in an embodiment, the first non-folding region NFA1 and the second non-folding region NFA2 may face each other, and the display device ED may be in-folded such that the display surface FS is not exposed to the outside. Also, referring to FIG. 1C, the display device ED according to an embodiment may be folded with respect to the first folding axis FX1 and be changed into an out-folded state where in the rear surface RS, one region overlapping the first non-folding region NFA1 and the other region overlapping the second non-folding region NFA2 face each other in a plan view.

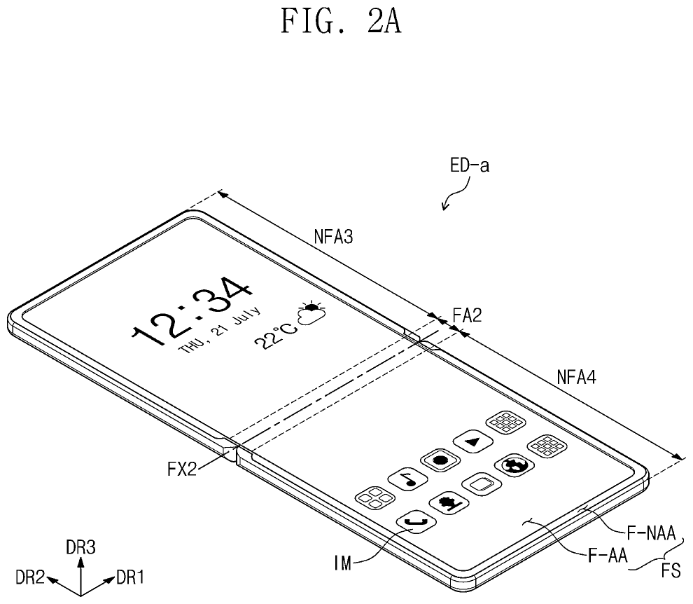

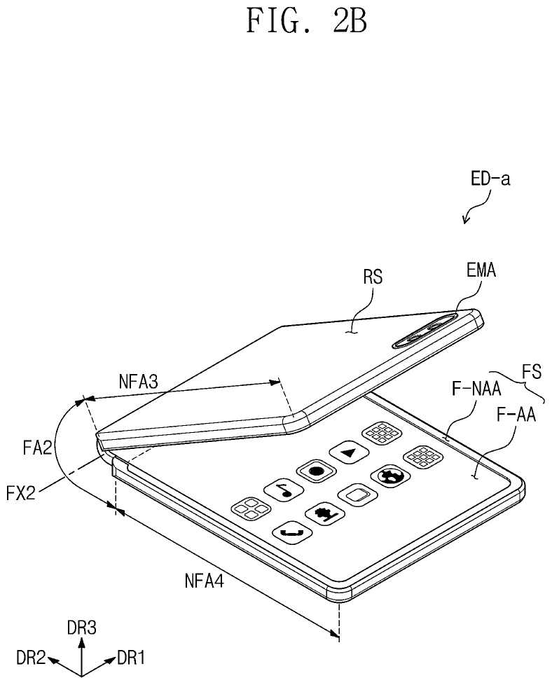

FIG. 2A is a perspective view illustrating an unfolded state of a display device ED-a according to another embodiment of the invention. FIG. 2B is a perspective view illustrating that the display device ED-a illustrated in FIG. 2A is being in-folded.

The display device ED-a according to an embodiment may be folded with respect to a second folding axis FX2 extending in one direction parallel to the first direction DR1. FIG. 2B illustrates that an extending direction of the second folding axis FX2 is parallel to an extending direction of a short side of the display device ED-a. However, an embodiment of the invention is not limited thereto.

The display device ED-a according to an embodiment may include at least one folding region FA2 and non-folding regions NFA3 and NFA4 adjacent to the folding region FA2. The non-folding regions NFA3 and NFA4 may be disposed to be spaced apart from each other with the folding region FA2 therebetween.

The folding region FA2 may have a predetermined curvature and a radius of curvature. In an embodiment, a first non-folding region NFA3 and a second non-folding region NFA4 may face each other, and the display device ED-a may be in-folded such that a display surface FS is not exposed to the outside.

Additionally, unlike what is illustrated in the drawing, in an embodiment, the display device ED-a may be out-folded such that the display surface FS is exposed to the outside. In an embodiment, a first display surface FS of the display device ED-a may be visible to a user in an unfolded state, and a second display surface RS of the display device ED-a may be visible to a user in an in-folded state. The second display surface RS may include an electronic module region EMA in which an electronic module including various components is disposed.

The display device ED-a according to an embodiment may include the second display surface RS, and the second display surface RS may be defined as a surface opposed to at least a portion of the first display surface FS. The second display surface RS may be visible to a user in an in-folded state. The second display surface RS may include the electronic module region EMA in which an electronic module including various components is disposed. In an embodiment, an image may be provided through the second display surface RS.

In an embodiment, the display devices ED and ED-a may be configured to repeatedly perform an in-folding or out-folding operation from an unfolding operation and vice versa, but an embodiment of the invention is not limited thereto. In an embodiment, the display devices ED and ED-a may be configured to select at least one of an unfolding operation, an in-folding operation, or an out-folding operation.

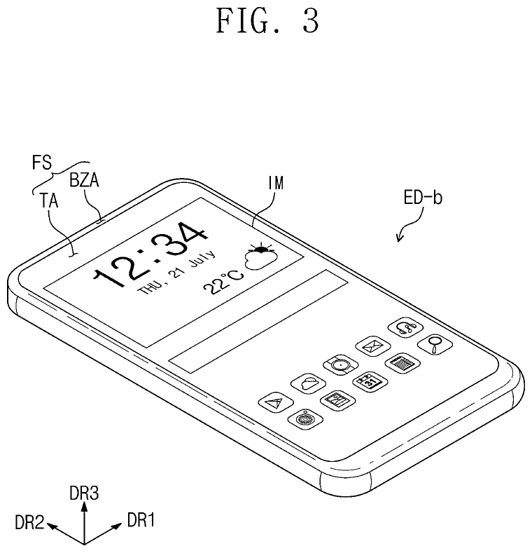

FIGS. 1A to 2B illustrate the display devices ED and ED-a as a foldable display device which is deformable into a folded form, but an embodiment of the invention is not limited thereto. The display devices ED and ED-a according to an embodiment may be a flexible display device which is deformable, for example, bendable or rollable. Additionally, as illustrated in FIG. 3, the display device ED-b according to an embodiment may be a rigid display device.

FIG. 3 is a perspective view of a display device according to still another embodiment of the invention. Referring to FIG. 3, on a plane, the display device ED-b according to an embodiment may have a quadrilateral shape, having rounded corners, in which short sides extend in the first direction DR1, and long sides extend in the second direction DR2 crossing the first direction DR1. However, an embodiment of the invention is not limited thereto, and on a plane, the display device ED-b may have various shapes, such as a rectangular, square, circular, polygonal, or irregular shape.

The display device ED-b may display, in the third direction DR3, the image IM on a display surface FS parallel to each of the first direction DR1 and the second direction DR2. The display surface FS, on which the image IM is displayed, may correspond to a front surface of the display device ED-b and a front surface of a later-described window. FIG. 3 exemplarily illustrates a flat display surface FS, but an embodiment of the invention is not limited thereto. The display surface FS of the display device ED-b according to an embodiment may further include a curved surface bent from at least one side of the flat surface in another embodiment.

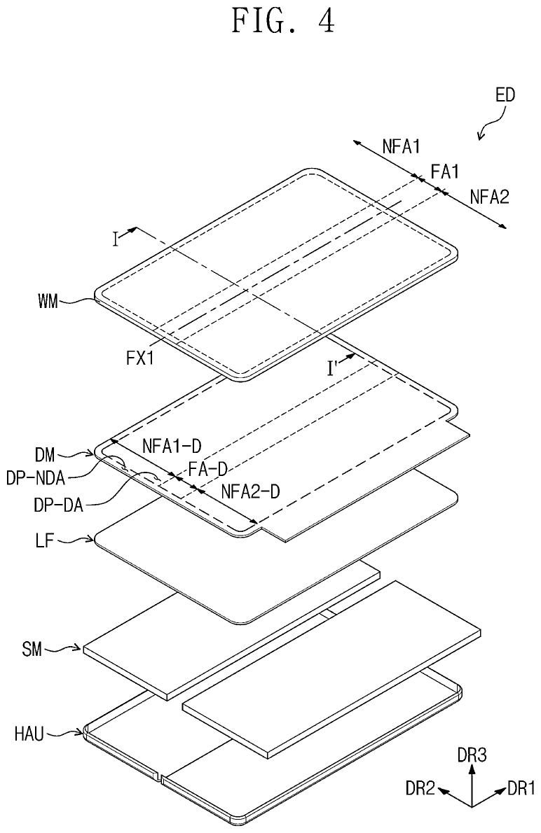

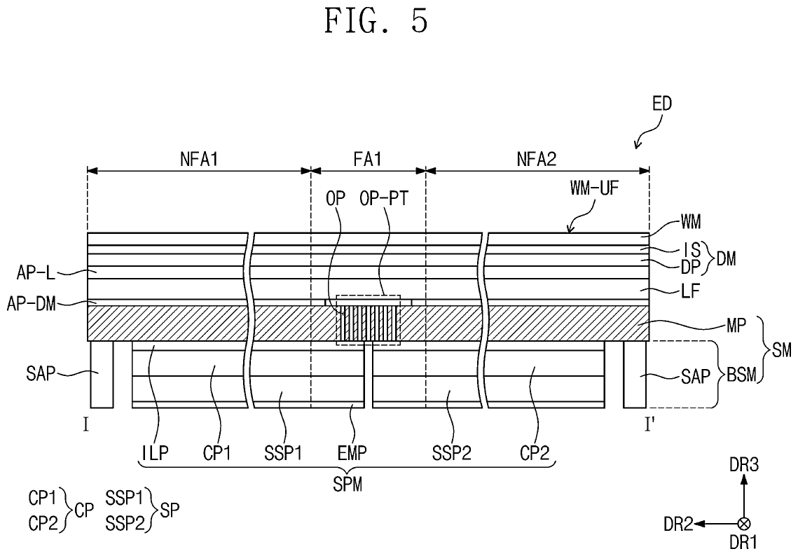

FIG. 4 is an exploded perspective view of a display device according to an embodiment. FIG. 4 exemplarily illustrates an exploded perspective view of the display device ED according to an embodiment, illustrated in FIG. 1A. FIG. 5 is a cross-sectional view of a display device according to an embodiment. FIG. 5 is a cross-sectional view illustrating a portion corresponding to line I-I′ of FIG. 4.

Referring to FIGS. 4 and 5, the display device ED according to an embodiment may include a display module DM and a window WM disposed on the display module DM. Additionally, the display device ED according to an embodiment may include a support module SM disposed below the display module DM. In FIGS. 4 and 5, the display device ED illustrated in FIGS. 1A to 1C is described as an embodiment, but the description made herein may also be similarly applied to the display device ED-a illustrated in FIGS. 2A and 2B.

The window WM may cover the entire exterior of the display module DM. The window WM may have a shape corresponding to the shape of the display module DM. Also, the display device ED according to an embodiment may include a housing HAU accommodating the display module DM, the support module SM, and/or the like. The housing HAU may be coupled to the window WM. The housing HAU may provide an inner space in which components of the display device ED may be accommodated. The housing HAU is disposed below the display module DM, and may accommodate the display module DM. The housing HAU may include glass, plastic or a metal material having relatively high rigidity. The housing HAU may absorb an external impact applied from the outside, or prevent infiltration of impurities/moisture into a display panel DP, thereby protecting the display panel DP. Although not illustrated in the drawing, the housing HAU may further include a hinge structure for facilitating a folding or bending operation.

In the display device ED according to an embodiment, the display module DM may display an image in response to an electrical signal and transmit/receive information about an external input. A display surface of the display module DM may be divided into a display region DP-DA and a non-display region DP-NDA. The display region DP-DA may be defined as a region in which an image provided from the display module DM is displayed.

The non-display region DP-NDA is adjacent to the display region DP-DA. In an embodiment, for example, the non-display region DP-NDA may surround the display region DP-DA. However, this is illustrated as an example. The non-display region DP-NDA may be defined as having various shapes, and is not limited to any one embodiment. According to an embodiment, the display region DP-DA of the display module DM may correspond to at least a portion of the active region F-AA (see FIG. 1A).

In the display device ED according to an embodiment, the display module DM may include a folding display part FA-D and non-folding display parts NFA1-D and NFA2-D. The folding display part FA-D may correspond to the folding region FA1 of the display device ED, and the non-folding display parts NFA1-D and NFA2-D may correspond to the non-folding regions NFA1 and NFA2 of the display device ED.

The window WM according to an embodiment is disposed on the display module DM. The window WM may include an optically transparent insulating material. The window WM may protect the display panel DP, a sensor layer IS, and/or the like. That is, the window WM may be a cover window which covers an upper part of the display module DM.

The image IM (see FIG. 1A) generated from the display module DP may pass through the window WM and be provided to a user. The window WM may provide a touch surface of the display device ED. In the display device ED including the folding region FA1, the window WM may be a flexible window capable of being folded.

The window WM may be provided as a display surface and a touch surface and exhibit excellent optical properties. The window WM according to an embodiment may have a high light transmittance of about 90% or more in a visible light range of about 380 nm to about 780 nm.

The window WM according to an embodiment may include a hard coating layer HC (see FIG. 8, and the like). Therefore, the display device ED including the window WM according to an embodiment may exhibit an excellent durability, and thus have improved folding properties and optical properties. The window WM according to an embodiment will be described later in more detail.

The display module DM may include the display panel DP and the sensor layer IS disposed on the display panel DP. Additionally, although not illustrated, the display module DM may further include an optical layer (not illustrated) disposed on the sensor layer IS. The optical layer (not illustrated) may function to reduce reflection of external light. In an embodiment, for example, the optical layer (not illustrated) may include a polarizing layer or a color filter layer. Even though not illustrated in FIG. 5, in another embodiment, the sensor layer IS may be omitted such that a bottom surface of the window WM may be in direct contact with an upper surface of the display panel DP.

The display panel DP may be configured to substantially generate an image. In an embodiment, for example, the display panel DP may be an organic light-emitting display panel, an inorganic light-emitting display panel, a quantum dot display panel, a micro LED display panel, a nano LED display panel, or a liquid crystal display panel. The display panel DP may be referred to as a display layer.

The sensor layer IS may be disposed on the display panel DP. The sensor layer IS may detect an external input applied from the outside. The external input may be a user's input. The user's input may include various types of external inputs such as a part of a user's body, light, heat, pen, or pressure.

In the display module DM according to an embodiment, the sensor layer IS may be disposed on the display panel DP through a continuous process. In this case, it may be understood that the sensor layer IS is directly disposed on the display panel DP. The wording, “being directly disposed on” means that another component is not disposed between the sensor layer IS and the display panel DP. That is, an additional adhesive member may not be disposed between the sensor layer IS and the display panel DP. Additionally, according to an embodiment of the invention, the sensor layer IS and the display panel DP may be bonded to each other via an adhesive member. The adhesive member may include a typical bonding agent or adhesive agent.

The display device ED according to an embodiment may include a lower film LF disposed below the display module DM. The lower film LF may be disposed below the display module DM, and may protect a lower part of the display module DM. The display device ED according to an embodiment may include a lower adhesive layer AP-L which bonds the display module DM and the lower film LF.

The lower film LF may be a polymer film. In an embodiment, for example, the lower film LF may include a polyethylene terephthalate (“PET”) film or a polyimide (“PI”) film. The lower film LF may prevent the occurrence of scratches on a rear surface of the display panel DP during the manufacturing process of the display panel DP. Additionally, the lower film LF protects the display panel DP against pressure provided from the outside, and may prevent the display panel DP from being deformed. The lower film LF may be a single film or have a structure in which a plurality of films are stacked.

The lower adhesive layer AP-L may be disposed between the display panel DP and the lower film LF. The lower adhesive layer AP-L may be an optically clear adhesive film (“OCA”) or an optically clear adhesive resin layer (“OCR”). However, an embodiment of the invention is not limited thereto, and the lower adhesive layer AP-L may include an acrylate-based adhesive, a silicone-based adhesive, or the like. Also, in another embodiment, the lower adhesive layer AP-L may be omitted.

The display device ED according to an embodiment may include a support module SM disposed below the display module DM. The support module SM may include a support plate MP and a lower support member BSM.

The support plate MP may be disposed on a lower side of the display module DM. The support plate MP may be disposed on a lower side of the lower film LF. In an embodiment, the support plate MP may include a metal material or a polymer material. In an embodiment, for example, the support plate MP may include stainless steel, aluminum, or alloys thereof. Additionally, unlike this, the support plate MP may include carbon fiber reinforced plastic (“CFRP”). However, an embodiment of the invention is not limited thereto, and the support plate MP may include a non-metallic material, plastic, glass fiber reinforced plastic, or glass in another embodiment.

A plurality of openings OP may be defined in the support plate MP. The support plate MP may include an opening pattern OP-PT including the plurality of openings OP. The opening pattern OP-PT may correspond to the folding region FA1.

The lower support member BSM may include a support member SPM and a filling part SAP. The support member SPM may overlap most of regions of the display module DM in a plan view. The filling part SAP may be disposed outside the support member SPM and overlap an exterior region of the display module DM in a plan view.

The lower support member BSM may include at least one of a cushion layer CP, a support layer SP, a shielding layer EMP, or an interlayer-bonding layer ILP. A configuration of the lower support member BSM is not limited to that illustrated in FIG. 5, and may vary according to the size, shape or operating characteristics, etc., of the display device ED. In an embodiment, for example, a portion of the cushion layer CP, the support layer SP, the shielding layer EMP, and the interlayer-bonding layer ILP may be omitted, or a stacking order thereof may be changed to another order different from that illustrated in FIG. 5. Alternatively, additional components, in addition to the illustrated components, may be further included. In an embodiment, for example, the lower support member BSM may further include a digitizer, and the like.

The cushion layer CP may be disposed on a lower side of the support plate MP. The cushion layer CP may prevent the support plate MP from being pressed and plastically deformed due to an external impact and force. Therefore, the cushion layer CP may improve an impact resistance of the display device ED. The cushion layer CP may include an elastomer such as a sponge, foam, or urethane resin. Additionally, the cushion layer CP may include at least one of an acylate-based polymer, a urethane-based polymer, a silicone-based polymer, or an imide-based polymer. However, an embodiment of the invention is not limited thereto.

Further, the cushion layer CP may include a first sub-cushion layer CP1 and a second sub-cushion layer CP2 spaced apart from each other in the second direction DR2. The first sub-cushion layer CP1 and the second sub-cushion layer CP2 may be spaced apart from each other in a region corresponding to the folding axis FX1. The cushion layer CP is provided as the first sub-cushion layer CP1 and the second sub-cushion layer CP2 which are spaced apart from each other in the folding region FA1, and thus the folding or bending property of the display device ED may be improved.

The support layer SP may include a metal material or a polymer material. The support layer SP may be disposed on a lower side of the cushion layer CP. In an embodiment, for example, the support layer SP may be a thin-film metal substrate.

The support layer SP may include a first sub-support layer SSP1 and a second sub-support layer SSP2 spaced apart from each other in the second direction DR2. The first sub-support layer SSP1 and the second sub-support layer SSP2 may be spaced apart from each other with respect to a region corresponding to the folding axis FX1. The support layer SP is provided as the first sub-support layer SSP1 and the second sub-support layer SSP2 which are spaced apart from each other in the folding region FA1, and thus the folding or bending property of the display device ED may be improved.

The shielding layer EMP may be disposed on a lower side of the support layer SP. The shielding layer EMP may be an electromagnetic wave shielding layer or a heat dissipation layer. Additionally, the shielding layer EMP may function as a bonding layer. The interlayer-bonding layer ILP may bond the support plate MP and the lower support member BSM. The interlayer-bonding layer ILP may be provided in a form of a bonding resin layer or adhesive tape. FIG. 5 illustrates that the interlayer-bonding layer ILP is separated as two parts spaced apart from each other in a region corresponding to the folding region FA1, but an embodiment of the invention is not limited thereto. The interlayer-bonding layer ILP may be provided as a single layer not spaced apart in the folding region FA1.

The filling part SAP may be disposed in the outer periphery of the cushion layer CP and the support layer SP. The filling part SAP may be disposed between the support plate MP and the housing HAU. The filling part SAP may fill the space between the support plate MP and the housing HAU and fix the support plate MP.

Also, the display device ED according to an embodiment may further include a module adhesive layer AP-DM disposed between the lower film LF and the support module SM. The module adhesive layer AP-DM may be an optically clear adhesive film (OCA) or an optically clear adhesive resin layer (OCR). Although not illustrated in the drawings, an additional adhesive layer may be further disposed between respective members included in the support module SM.

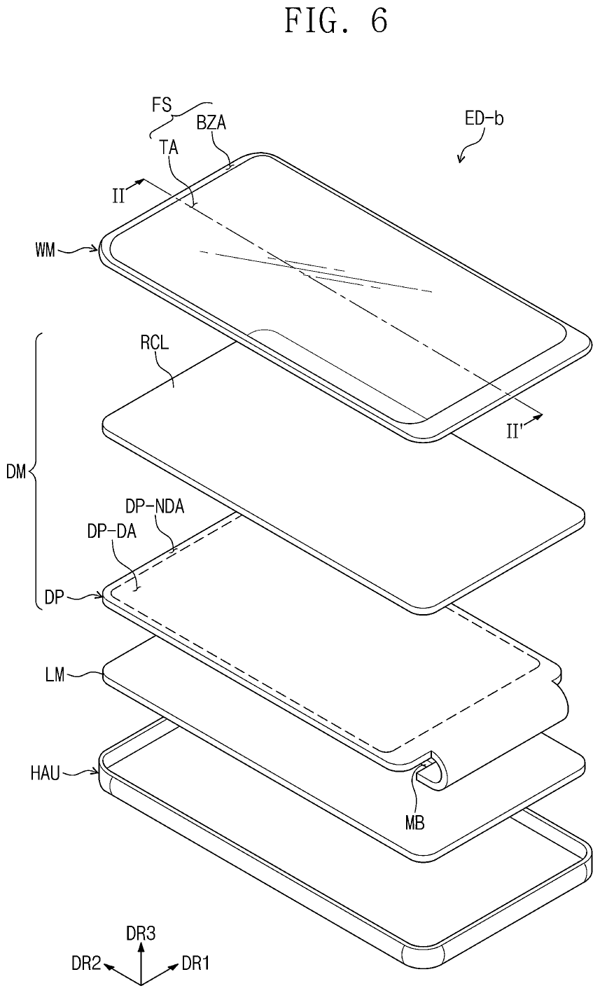

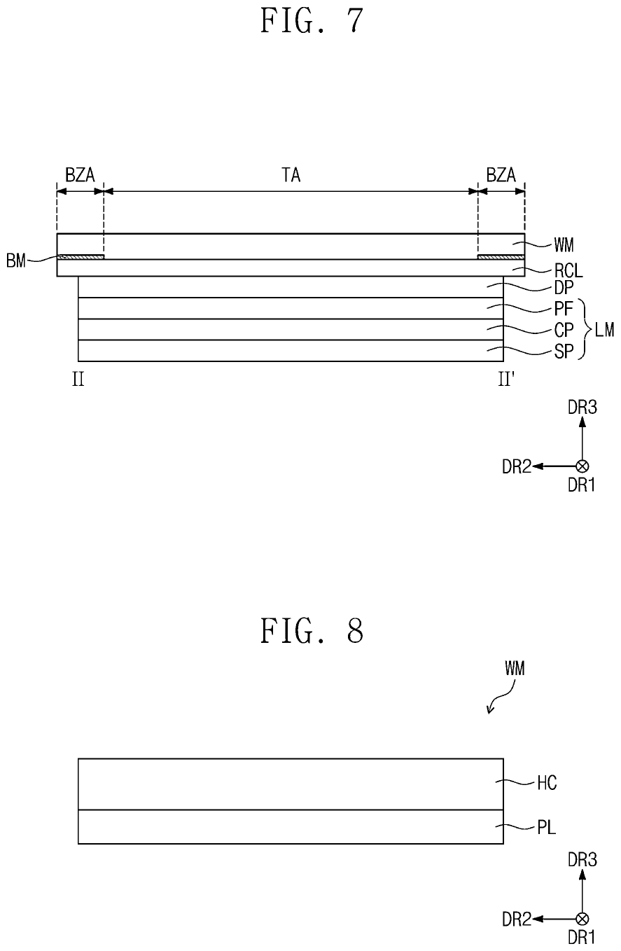

FIG. 6 is an exploded perspective view of a display device according to another embodiment. FIG. 6 exemplarily illustrates an exploded perspective view of the display device ED-b according to an embodiment, illustrated in FIG. 3. FIG. 7 is a cross-sectional view of a display device according to an embodiment. FIG. 7 is a cross-sectional view illustrating a portion corresponding to line II-II′ of FIG. 6.

Referring to FIGS. 6 and 7, the display device ED-b according to an embodiment may include a window WM, a display module DM, a lower module LM, and a housing HAU. The display module DM may include a display panel DP and an optical layer RCL. The window WM and the housing HAU may be coupled to constitute the exterior of the display device ED-b.

The window WM may be disposed on the display module DM. The window WM may have a shape corresponding to the shape of the display module DM. The window WM may cover the entire exterior of the display module DM and protect the display module DM against external impacts and scratches.

A display surface FS of the window WM may include a transmission region TA and a bezel region BZA. The transmission region TA of the window WM may be an optically transparent region. The window WM may transmit the image IM provided from the display module DM through the transmission region TA.

The bezel region BZA of the window WM may overlap a light blocking layer BM (see FIG. 7) in a plan view. The light blocking layer BM may be provided on a lower surface of the window WM adjacent to the display module DM. The light blocking layer BM may be a rigid substrate including a material having a predetermined color or may be an ink printing layer. The light blocking layer BM may be a layer formed while including a pigment or dye. The light blocking layer BM may be disposed in an edge region of the window WM. The bezel region BZA of the window WM may prevent some components, of the display panel DP disposed to overlap the bezel region BZA, from being viewed from the outside.

The bezel region BZA may be adjacent to the transmission region TA. A shape of the transmission region TA may be substantially defined by the bezel region BZA. In an embodiment, for example, the bezel region BZA may be disposed outside the transmission region TA and surround the transmission region TA. However, this is exemplarily illustrated. The bezel region BZA may be adjacent to only one side of the transmission region TA or be omitted. Additionally, the bezel region BZA may be disposed not on a front surface but on a side surface of the display device ED-b.

The window WM included in the display device ED-b according to an embodiment includes a hard coating layer HC (see FIG. 8, and the like). Therefore, the display device ED including the window WM according to an embodiment may exhibit an excellent durability, and thus have improved folding properties and optical properties. The window WM according to an embodiment will be described later in more detail with reference to FIG. 8, and the like.

The optical layer RCL may be disposed between the display panel DP and the window WM. The optical layer RCL may reduce reflectance for light incident from the outside. The optical layer RCL may include at least one of a retarder, a polarizer, a polarizing film, or a polarizing filter. In an embodiment, the optical layer RCL may include a polarizing film. In this case, the optical layer RCL may be attached to the display panel DP via an adhesive layer. However, this is presented as an example, and an embodiment of the invention is not limited thereto. For another example, the optical layer RCL may include a color filter. Also, the sensor layer IS, described with reference to FIG. 5, may be disposed between the optical layer RCL and the display panel DP.

The display panel DP may be disposed between the window WM and the lower module LM. The display panel DP may display an image IM in response to an electrical signal. The display panel DP according to an embodiment may be a light-emitting display panel, but is not particularly limited thereto. In an embodiment, for example, the display panel DP may be an organic light-emitting display panel, an inorganic light-emitting display panel, an organic-inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the organic-inorganic light-emitting display panel may include an organic-inorganic light-emitting material. A light-emitting layer of the quantum dot light-emitting display panel may include quantum dots, quantum rods, and/or the like.

The image IM provided from the display device ED-b may be displayed on a front surface of the display panel DP. The front surface of the display panel DP may include a display region DP-DA and a non-display region DP-NDA. The display region DP-DA may be a region which is activated in response to an electrical signal and displays images IM. According to an embodiment, the display region DP-DA of the display panel DP may correspond to the transmission region TA of the window WM. In this specification, the wording “a region/portion corresponds to an another region/portion” means “overlapping each other” and is not limited as having the same area and/or shape.

The non-display region DP-NDA may be adjacent to the outside of the display region DP-DA. In an embodiment, for example, the non-display region DP-NDA may surround the display region DP-DA. However, an embodiment of the invention is not limited thereto, and the non-display region DP-NDA may be defined as having various shapes.

The non-display region DP-NDA may be a region in which a driving circuit or a driving line for driving elements disposed in the display region DP-DA, various types of signal lines, pads, or the like for providing electrical signals may be disposed. The non-display region DP-NDA of the display panel DP may correspond to the bezel region BZA of the window WM. The bezel region BZA may prevent components, of the display panel DP disposed in the non-display region DP-NDA, from being viewed from the outside.

The display device ED-b may include a circuit board MB connected to the display panel DP. The circuit board MB may be connected to one end of the display panel DP extending in the first direction DR1. The circuit board MB may generate an electrical signal provided to the display panel DP. In an embodiment, for example, the circuit board MB may include a timing controller which generates a signal provided to a driver of the display panel DP in response to control signals received from the outside.

At least a portion of the non-display region DP-NDA of the display panel DP may be bent. A portion of the display panel DP connected to the circuit board MB may be bent such that the circuit board MB is headed toward a rear surface of the display panel DP. The circuit board MB may be disposed, on a plane, to overlap the rear surface of the display panel DP and be assembled. However, an embodiment of the invention is not limited thereto, and the display panel DP may be connected to the circuit board MB via a flexible circuit board connected to one end of each of the display panel DP and the circuit board MB in another embodiment.

The display device ED-b according to an embodiment may include a lower module LM below the display panel DP. The lower module LM may include a panel protective layer PF, a cushion layer CP, and a support layer SP.

The panel protective layer PF is disposed below the display panel DP, and thus may protect the display panel DP against an impact. The panel protective layer PF may be bonded to a lower surface of the display panel DP via an adhesive layer (not illustrated). However, the adhesive layer may be omitted.

The cushion layer CP may be disposed below the panel protective layer PF. The cushion layer CP may absorb an impact transmitted from below the display panel DP. Therefore, the cushion layer CP may improve the impact resistance of the display device ED-b. The cushion layer CP may include an elastomer such as a sponge, foam, or urethane resin. The cushion layer CP may include at least one of an acylate-based polymer, a urethane-based polymer, a silicone-based polymer, or an imide-based polymer. However, an embodiment of the invention is not limited thereto.

The support layer SP is disposed below the cushion layer CP, and thus may support the display panel DP and the cushion layer CP. The support layer SP may be a thin-film metal substrate having a rigidity greater than a predetermined rigidity. In an embodiment, for example, the support layer SP may be a stainless steel plate. The support layer SP may have a black color to block external light incident onto the display panel DP.

The housing HAU may provide an inner space in which components of the display device ED-b may be accommodated. The content of the housing HAU described with reference to FIG. 4 may be similarly applied to the housing HAU included in the display device ED-b.

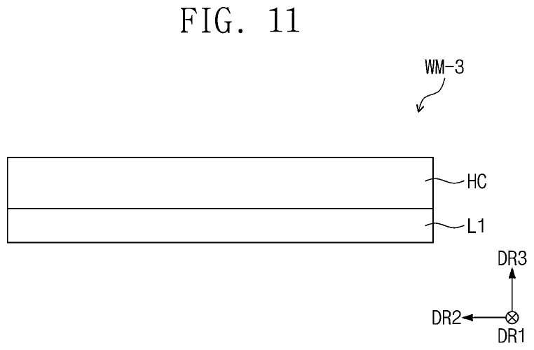

FIGS. 8 to 11 are cross-sectional views of a window according to embodiments, respectively. FIGS. 8 to 11 are cross-sectional views illustrating windows WM, WM-1, WM-2, and WM-3 including a hard coating layer HC according to embodiments, respectively. The windows WM, WM-1, WM-2, and WM-3 illustrated in FIGS. 8 to 11 may each be the window WM according to an embodiment, which are illustrated in FIGS. 4 to 7. In an embodiment, for example, the windows WM, WM-1, and WM-2 illustrated in FIGS. 8 to 10 may each be used as the cover windows of the display devices ED and ED-a described with reference to FIGS. 1A to 5. The window WM-3 illustrated in FIG. 11 may be used as the cover window of the display device ED-b described with reference to FIGS. 3, 6, and 7. However, an embodiment of the invention is not limited thereto, and the windows WM, WM-1, and WM-2 illustrated in FIGS. 8 to 10 may be applied to the display device ED-b illustrated in FIG. 3, etc., and the window WM-3 illustrated in FIG. 11 may also be applied to the display devices ED and ED-a illustrated in FIGS. 1A to 5.

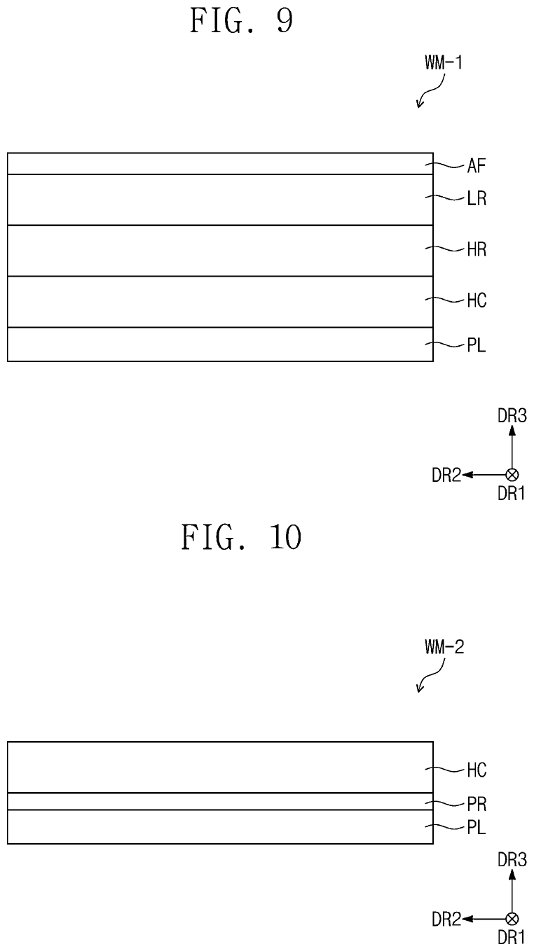

Referring to FIG. 8, the window WM according to an embodiment may include a hard coating layer HC formed from a resin composition according to an embodiment. Hereinafter, the following description of the hard coating layer HC included in the window WM may be similarly applied to not only the window WM, according to an embodiment, illustrated in FIG. 8, but also configurations of the windows WM-1, WM-2, and WM-3 according to an embodiment, which are described with reference to FIGS. 9 to 11.

The hard coating layer HC may be formed by curing a resin composition according to an embodiment (hereinafter, first resin composition). When ultraviolet rays are emitted during the process of curing the first resin composition, at least a portion of compounds included in the first resin composition may be cross-linked due to a polymerization reaction. Therefore, the hard coating layer HC according to the invention may include a polymer derived from the first resin composition.

Since the window WM according to an embodiment includes the hard coating layer HC formed from the first resin composition, the window WM may be provided on the display module DM without a base layer such as a glass substrate and a plastic substrate. Therefore, cracks may be prevented from occurring on a surface of the window WM according to an embodiment when folding operations are performed multiple times.

The first resin composition may include a photoinitiator, a fluorine-based compound, an acrylate-based compound, and a reactive diluent, and further include an ultraviolet absorber and/or an additive.

The photoinitiator is a material which generates radicals or ions when irradiated with light, and may include at least one of an acetophenone-based compound, a sulfonium-based compound, or a benzophenone-based compound. One or more types of photoinitiators may be included in the first resin composition. When the first resin composition includes a plurality of photoinitiators, the photoinitiators may be activated in response to ultraviolet light having different central wavelengths, respectively.

In an embodiment, for example, the photoinitiator may include at least one of Irgacure 651 (benzyldimethyl ketal), Irgacure 184 (1-hydroxy-cyclohexyl-phenyl-ketone), or Irgacure 819 (bis(2,4,6-trimethyl benzoyl)-phenylphosphine oxide), but an embodiment of the invention is not limited thereto.

The first resin composition may contain the photoinitiator in an amount of about 0.1% by weight or more and less than about 5% by weight with respect to the total weight of the first resin composition. In a case where the first resin composition contains the photoinitiator in an amount of the above-described range, a polymerization reaction may sufficiently occur during light irradiation for forming the hard coating layer HC.

The first resin composition may include a fluorine-based compound such that the surface of the window WM exhibits a slip property or anti-fingerprint property. The fluorine-based compound may include perfluoropolyether. The perfluoropolyether may be a compound represented by Chemical Formula F:

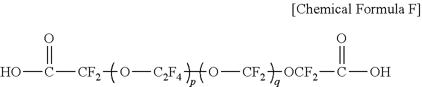

In Chemical Formula F, p and q may each independently be an integer of 10 to 50, but an embodiment of the invention is not limited thereto.

Although the hard coating layer HC according to an embodiment does not include a boundary surface clearly defined by separate layers, the fluorine-based compound may be mostly disposed in an upper portion of the hard coating layer HC. Therefore, when the hard coating layer HC is disposed on the outermost layer of the window WM, the window WM may exhibit an excellent antifouling property and durability.

The first resin composition may contain the fluorine-based compound in an amount of about 0.1% by weight or more and less than about 5% by weight with respect to the total weight of the first resin composition. When the first resin composition contains the fluorine-based compound in an amount of the above-described range, the window WM including the hard coating layer HC may have the improved antifouling property and durability.

The first resin composition may include an acrylate-based compound so as to exhibit excellent reactivity and curability during the curing and to impart appropriate hardness and flexibility to the hard coating layer HC. The acrylate-based compound may include at least one of polyester acrylate, epoxy acrylate, urethane acrylate, or ethylene glycol acrylate. In an embodiment, for example, the polyester acrylate has the excellent reactivity, and the epoxy acrylate has the excellent hardness, flexibility, and curability. Additionally, the urethane acrylate has excellent curability and is advantageous in forming a hard coating film. The first resin composition may selectively include polyester acrylate, epoxy acrylate, urethane acrylate, etc., which exhibit the above-described characteristics. The first resin composition according to an embodiment of the invention may be used by mixing one or more types of the acrylate-based compounds described above.

The acrylate-based compound may have a molecular weight of about 2000 g/mol to about 15000 g/mol. In an embodiment, for example, the polyester acrylate, the epoxy acrylate, the urethane acrylate, and the ethylene glycol acrylate may each have a molecular weight of about 2000 g/mol to about 15000 g/mol. When the acrylate-based compound has a molecular weight in the above-described range, the hard coating layer HC may have improved hardness and adhesiveness.

The acrylate-based compound may include a monofunctional or polyfunctional oligomeric acrylate. In an embodiment, for example, the polyester acrylate may include one or more (meth)acryloyl groups having a polyester bond per oligomer. The epoxy acrylate may include one or more (meth)acryloyl groups having an epoxy bond per oligomer. The urethane acrylate may include one or more (meth)acryloyl groups having a urethane bond per oligomer. The ethylene glycol acrylate may include one or more (meth)acryloyl groups having an ethylene glycol bond per oligomer. In this specification, the (meth)acryloyl group represents an acryloyl group or methacryloyl group, and the (meth)acrylic represents acrylic or methacrylic.

In an embodiment, the first resin composition is an acrylate-based compound, and may include a first monomer and a second monomer. The first monomer may be a compound including four to six (meth)acryloyl groups in a molecule. The second monomer may be a compound including three (meth)acryloyl groups in a molecule.

The first monomer may be contained in an amount of about 40 percentages by weight (wt %) to about 70 wt % with respect to 100 wt % of the total first resin composition. When the first resin composition contains the first monomer in an amount of the above-described range, the hard coating layer HC may be increased in hardness, and thus improved in wear resistance.

The oligomeric acrylate and the second monomer may each be contained in an amount of about 10 wt % to about 20 wt % with respect to 100 wt % of the total first resin composition. Since the first resin composition contains the oligomeric acrylate and the second monomer in an amount of the above-described range, the hardness of the hard coating layer HC is adjusted, and thus the adhesiveness of the hard coating layer HC may be effectively improved.

To provide the adhesiveness and flexibility to the hard coating layer HC, the first resin composition may further include, as an acrylate-based compound, alkyl (meth)acrylate, which is a non-ultraviolet curing resin monomer, in addition to polyester acrylate, epoxy acrylate, urethane acrylate, and/or ethylene glycol acrylate.

The alkyl (meth)acrylate may be (meth)acrylate having an alkyl group. The alkyl (meth)acrylate may be (meth)acrylate containing an unsubstituted alkyl group having 1 to 10 carbon atoms. In an embodiment, for example, the alkyl (meth)acrylate may include at least one of methyl(meth)acrylate, ethyl (meth)acrylate, propyl (meth)acrylate, n-butyl (meth)acrylate, t-butyl (meth)acrylate, iso-butyl (meth)acrylate, pentyl (meth)acrylate, hexyl (meth)acrylate, heptyl (meth)acrylate, octyl (meth)acrylate, nonyl (meth)acrylate, or iso-decyl (meth)acrylate. The first resin composition according to an embodiment may further include, as an acrylate-based compound, n-butyl (meth)acrylate, t-butyl (meth)acrylate, or iso-butyl (meth)acrylate.

The first resin composition according to an embodiment may include a reactive diluent. Since the first resin composition includes the reactive diluent, the viscosity of the composition may be adjusted, and thus the curability, adhesiveness, and the like may be effectively improved.

The first resin composition may have a viscosity of about 1000 centipoise (cps) or less to facilitate discharge when forming the hard coating layer HC. To this end, the first resin composition may include, as the reactive diluent, at least one of polyester acrylate or polyether acrylate, which has a low molecular weight. In an embodiment, for example, the polyester acrylate and polyether acrylate may each have a molecular weight of about 1000 g/mol or less, but an embodiment of the invention is not limited thereto. The polyester acrylate and polyether acrylate may each have a molecular weight of greater than 0 and about 1000 g/mol or less.

In an embodiment, for example, the reactive diluent may be contained in an amount of about 1 wt % to about 5 wt % with respect to 100 wt % of the total first resin composition. When the first resin composition contains the reactive diluent in an amount of the above-described range, the first resin composition is applied in a uniform amount and to a uniform thickness, and thus the adhesiveness of the hard coating layer HC may be effectively improved.

The first resin composition may further include an additive. The additive may be a highly flexible material and be represented by Chemical Formula 1 or Chemical Formula 2:

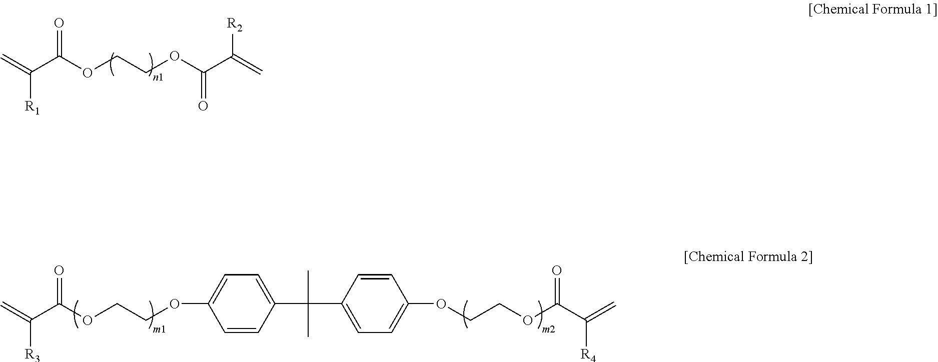

In Chemical Formula 1 and Chemical Formula 2, R1 to R4 may each be independently a hydrogen atom, or an unsubstituted methyl group. In an embodiment, for example, R1 to R4 may each be a hydrogen atom. In Chemical Formula 1 and Chemical Formula 2, n1 may be an integer of 1 to 10. m1 and m2 may each be independently an integer of 1 to 20, and a sum of m1 and m2 may be 10 to 30. In an embodiment, for example, the sum of m1 and m2 may be 10 or 30, but an embodiment of the invention is not limited thereto.

In an embodiment, the additive represented by Chemical Formula 1 may be represented by Chemical Formula 1-1 or Chemical Formula 1-2:

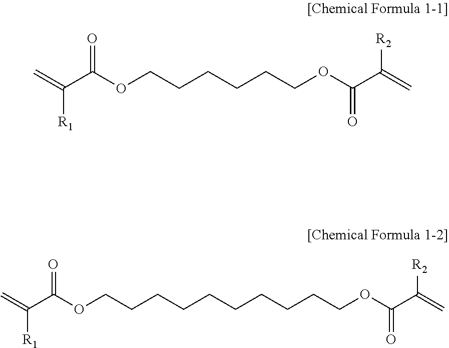

Chemical Formula 1-1 and Chemical Formula 1-2 each represent the case where the number of n1 in Chemical Formula 1 is specified. Chemical Formula 1-1 corresponds to the case where n1 in Chemical Formula 1 is 3. In an embodiment, for example, Chemical Formula 1-1 may be 1,6-hexanediol di(meth)acrylate. Chemical Formula 1-2 corresponds to the case where n1 in Chemical Formula 1 is 5. In an embodiment, for example, Chemical Formula 1-2 may be 1,10-decanediol di(meth)acrylate.

In Chemical Formula 1-1 and Chemical Formula 1-2, the description of Chemical Formula 1 may be similarly applied to R₁ and R₂.

In an embodiment, the additive represented by Chemical Formula 2 may be represented by Chemical Formula 2-1 or Chemical Formula 2-2:

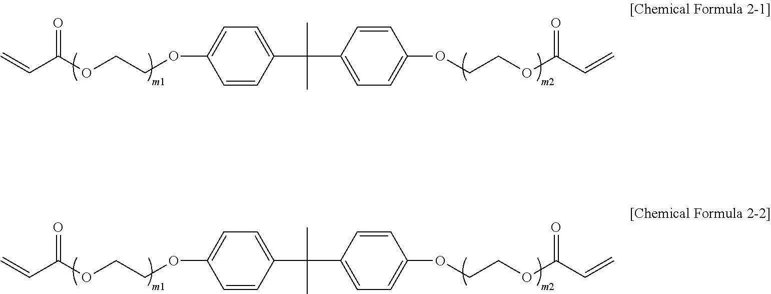

In Chemical Formula 2-1, the sum of m1 and m2 may be 10, and in Chemical Formula 2-2, the sum of m1 and m2 may be 30. In an embodiment, for example, Chemical Formula 2-1 may be Bisphenol A (EO)₁₀ Diacrylate, and Chemical Formula 2-2 may be Bisphenol A (EO)₃₀ Diacrylate.

The first resin composition may include an additive by adjusting an additive content such that the hard coating layer HC may exhibit excellent adhesiveness and high flexibility. In an embodiment, for example, the additive may be contained in an amount of about 40 wt % to about 70 wt % with respect to 100 wt % of the total first resin composition. When the first resin composition contains the additive in an amount of the above-described range, the hard coating layer HC may have the improved flexibility and exhibit excellent adhesiveness. However, an embodiment of the invention is not limited thereto.

The first resin composition may further include an ultraviolet absorber which has an effect of blocking transmission of ultraviolet rays with a wavelength of about 410 nm or less. The ultraviolet absorber may include at least one of a salicylic acid-based compound, a benzophenone-based compound, a benzotriazole-based compound, a cyanoacrylate-based compound, a nickel phenolate-based compound, or a hindered amine-based compound. In an embodiment, for example, the ultraviolet absorber may include at least one of the benzophenone-based compound or the benzotriazole-based compound.

In an embodiment, the ultraviolet absorber may include at least one of 2-(2-hydroxy-5-methylphenyl)benzotriazole, 2-(3-ter-butyl-2-hydroxy-5-methylphenyl)-2H-5-chlorobenzotriazole, 2-(2′-hydroxy-5′-ter-octylphenyl)benzotriazole, or 2-hydroxy-4-n-octoxybenzophenone.

The ultraviolet absorber may be contained in an amount of about 1 wt % to about 5 wt % with respect to 100 wt % of the first resin composition. When the first resin composition contains the ultraviolet absorber in an amount of the above-described range, the hard coating layer HC formed from the first resin composition according to an embodiment may block most of ultraviolet rays with a wavelength of about 350 nm or less. Therefore, the window WM according to an embodiment may protect underlying layers of the hard coating layer HC.

The window WM according to an embodiment may include an adhesive layer PL disposed below the hard coating layer HC. The adhesive layer PL may be disposed between the hard coating layer HC and the display module DM (see FIG. 4). The adhesive layer PL may be in direct contact with a lower surface of the hard coating layer HC. The adhesive layer PL may be an optically clear adhesive film (OCA) or a pressure sensitive adhesive layer (“PSA”).

The window WM, according to an embodiment, which includes the adhesive layer PL and the hard coating layer HC may be directly disposed on the display module DM (FIG. 4). The window WM, which is directly disposed on the display module DM (see FIG. 4), may exhibit such an excellent folding property that cracks are prevented from occurring on the surface of the window WM even in a low curvature structure (for example, OutFolding 3R) when a folding operation is performed multiple times.

In an embodiment, for example, the hard coating layer HC may have a thickness of about 50 μm to about 100 μm. The adhesive layer PL may have a thickness of about 100 μm or less. In an embodiment, for example, the adhesive layer PL may have a thickness of about 10 μm to about 100 μm, but an embodiment of the invention is not limited thereto. When the adhesive layer PL and the hard coating layer HC of the window WM may each have the above-described thickness range, the window WM according to an embodiment may exhibit excellent durability and a folding property.

FIG. 9 exemplarily illustrates the window WM-1 further including a high refractive layer HR, a low refractive layer LR, and a functional layer AF, compared to the window WM of FIG. 8, and FIG. 10 exemplarily illustrates the window WM-2 further including a primer layer PR, compared to the window WM of FIG. 8. The contents duplicated with those described previously will be omitted in FIGS. 9 and 10, and the following description will be mainly focused on the differences.

Referring to FIG. 9, the window WM-1 according to an embodiment may include a hard coating layer HC, a high refractive layer HR, a low refractive layer LR and a functional layer AF. Additionally, the window WM-1 may include an adhesive layer PL disposed below the hard coating layer HC. The hard coating layer HC, the high refractive layer HR, the low refractive layer LR, and the functional layer AF may be sequentially provided on the adhesive layer PL.

The high refractive layer HR may be disposed on the hard coating layer HC. The high refractive layer HR may be directly disposed on the hard coating layer HC. A lower surface of the high refractive layer HR may be in contact with an upper surface of the hard coating layer HC.

The high refractive layer HR may have a first refractive index greater than the low refractive layer LR. In an embodiment, for example, the high refractive layer HR may have a first refractive index of about 1.6 or more. In an embodiment, for example, the first refractive index may be about 1.6 to about 1.67. As the first refractive index of the high refractive layer HR according to an embodiment satisfies the above-described range, a surface reflectance of the window WM-1 may be reduced.

The high refractive layer HR may include at least one of tin oxide (SnOₓ), titanium oxide (TiOₓ), zirconium oxide (ZrOₓ), or a sulfur atom. The tin oxide, titanium oxide, and zirconium oxide included in the high refractive layer HR may be represented by SnOₓ, TiOₓ, and ZrOₓ (where 0<x<3), respectively. In an embodiment, for example, the tin oxide may be SnO₂, but an embodiment of the invention is not limited thereto.

In an embodiment, the high refractive layer HR may have a thickness of about 80 nm to about 110 nm. In an embodiment, for example, the high refractive layer HR may have a thickness of about 100 nm. When the high refractive layer HR has a thickness in a range of about 80 nm to about 110 nm, the window WM-1 according to an embodiment may exhibit excellent optical properties of high light transmittance and low reflectance. Additionally, the window WM-1, according to an embodiment, which includes the high refractive layer HR having the above-described thickness range has excellent impact resistance, etc., and thus may have improved durability.

The low refractive layer LR may be disposed on the high refractive layer HR. The low refractive layer LR may be directly disposed on the high refractive layer HR. A lower surface of the low refractive layer LR may be in contact with an upper surface of the high refractive layer HR. The low refractive layer LR may be disposed to be adjacent to the display surface FS (see FIG. 1A) exposed to the outside than the high refractive layer HR. However, an embodiment of the invention is not limited thereto.

The second refractive index of the low refractive layer LR may be adjusted according to a combination with a refractive index of the high refractive layer HR such that the overall reflectance of the window WM-1 becomes about 6% or less. The window WM-1, according to an embodiment, which includes the low refractive layer LR may have a reflectance of about 6% or less with respect to light having a wavelength of about 360 nm to about 700 nm.

The second refractive index of the low refractive layer LR may be lower than the first refractive index of the high refractive layer HR. The second refractive index may be about 1.5 or less. In an embodiment, for example, the second refractive index of the low refractive layer LR may be about 1.42 to about 1.50. However, an embodiment of the invention is not limited thereto, and the second refractive index of the low refractive layer LR may be adjusted within a range in which the window WM maintains a low reflectance of about 6% or less.

The low refractive layer LR may include hollow particles and a base resin, and further include an additive. In an embodiment, for example, the low refractive layer LR may include a polymer derived from a second resin composition including hollow particles and a base resin. Additionally, the second resin composition may further include one or more additives selected from a filler, a slip agent, a light stabilizer, a thermal polymerization inhibitor, a leveling agent, a lubricant, an antifouling agent, a thickener, a surfactant, an antifoaming agent, an antistatic agent, a dispersant, an initiator, a coupling agent, an antioxidant, a UV stabilizer, a colorant, and the like.

In an embodiment, for example, with respect to the total weight of the second resin composition, the hollow particles may be contained in an amount of about 25 wt % to about 35 wt %. When the amount of the hollow particles contained in the second resin composition satisfies the above-described range, the low refractive layer LR formed from the second resin composition may sufficiently exhibit the low reflectance while improving the mechanical durability of the low refractive layer LR. That is, when the hollow particles are contained in an amount of about 25 wt % to about 35 wt % with respect to the total low refractive layer LR, the window WM-1 according to an embodiment may exhibit further improved optical properties and durability.

In an embodiment, for example, when the hollow particles are contained in an amount of less than about 25 wt % with respect to the total weight of the second resin composition, the second refractive index value of the low refractive layer LR increases, and thus a light extraction function of the low refractive layer LR may deteriorate in consideration of the relationship with other members. Additionally, when the hollow particles are contained in an amount of greater than about 35 wt % with respect to the total weight of the second resin composition, the amount of the hollow particles contained in the low refractive layer LR relatively increases, and thus the mechanical strength of the low refractive layer LR may decrease.

The hollow particles may each have a core-shell form. The hollow particles may each include a core portion and a shell portion surrounding the core portion. The core portion may be defined by the shell portion. The shell portion may be a layer formed from an inorganic material. The shell portion may include SiO₂. That is, the hollow particles in the low refractive layer LR according to an embodiment may be hollow silica.

The hollow particles may have an average diameter of about 30 nm to about 70 nm. When the average diameter of the hollow particles satisfies the above-described range, the thickness and the second refractive index value of the low refractive layer LR may be optimized.

The base resin included in the low refractive e layer LR may include an acylate-based resin, a urethane-based resin, a fluorine-based resin, an epoxy-based resin, a polyester-based resin, a polyamide-based resin, a silicone-based resin, or a combination thereof. The base resin may be provided in the form of a monomer or oligomer. The base resin may be liquid before being cured.

In an embodiment, the low refractive layer LR may have a thickness of about 60 nm to about 90 nm. In an embodiment, for example, the low refractive layer LR may have a thickness of about 70 nm. When the low refractive layer LR has a thickness in a range of about 60 nm to about 90 nm, the window WM-1 according to an embodiment may exhibit excellent optical properties of high light transmittance and low reflectance. Additionally, the window WM-1, according to an embodiment, which includes the low refractive layer LR having a thickness in a range of about 60 nm to about 90 nm has excellent impact resistance, etc., and thus may exhibit improved durability.

The window WM-1 according to an embodiment of the invention may include a two-layered structure in which a layer with a relatively high refractive index and a layer with a relatively low refractive index are sequentially stacked in a thickness direction. Accordingly, the window WM-1 may have an improved anti-reflection effect.

The window WM-1 according to an embodiment may include a functional layer AF disposed on the low refractive layer LR. The functional layer AF may be directly disposed on the low refractive layer LR. Additionally, the functional layer AF may be disposed on the low refractive layer LR via the adhesive layer (not illustrated). The functional layer AF may be disposed on the outermost portion of the window WM-1.

The functional layer AF may be composed of a single layer or a plurality of layers. The functional layer AF may include at least one of a hard coating layer, an anti-fingerprint layer, or an anti-scattering layer. In an embodiment, the functional layer AF may include a fluorine-containing compound. In an embodiment, the functional layer AF including the fluorine-containing compound may be an anti-fingerprint layer.

The functional layer AF may have a thickness of about 10 nm to about nm. When the functional layer AF has a thickness in the above-described range, the functional layer AF may have not only the excellent antifouling property but also the excellent durability.

In an embodiment, the functional layer AF may include perfluoropolyether. The perfluoropolyether may be a compound represented by the above-described Chemical Formula F.

Referring to FIG. 10, the window WM-2 according to an embodiment may further include a primer layer PR. The primer layer PR may be disposed between the adhesive layer PL and the hard coating layer HC. A lower surface of the primer layer PR may be in direct contact with an upper surface of the adhesive layer PL, and an upper surface of the primer layer PR may be in direct contact with a lower surface of the hard coating layer HC.

In an embodiment, the primer layer PR may include silicon oxide and an ultraviolet absorber. The silicon oxide included in the primer layer PR may be contained in an amount of about 90 wt % to about 95 wt % with respect to the total weight of the primer layer PR. Additionally, the ultraviolet absorber included in the primer layer PR may be contained in an amount of about 1 wt % to about 10 wt % with respect to the total weight of the primer layer PR. When the primer layer PR contains the silicon oxide and the ultraviolet absorber in the above-described ranges, respectively, an adhesiveness between the hard coating layer HC and the adhesive layer PL may be further improved, and most of ultraviolet rays with a wavelength of about 350 nm or less may be blocked to thereby protect layers disposed below the window WM-2.

In an embodiment of the invention, the description of the ultraviolet absorber included in the hard coating layer HC described with reference to FIG. 8 may be similarly applied to the ultraviolet absorber included in the primer layer PR, except for a content range.

FIG. 11 exemplarily illustrates a window WM-3 including a first layer L1 and not including the adhesive layer PL, compared to the window WM of FIG. 8. In the description of FIG. 11, the contents duplicated with those described with reference to FIGS. 1A to 10 will be omitted, and the following description will be mainly focused on the differences.

Referring to FIG. 11, the window WM-3 according to an embodiment may include a first layer L1 and a hard coating layer HC. The first layer L1 may be disposed below the hard coating layer HC and on the display module DM (see FIG. 6). A lower surface of the first layer L1 may be in direct contact with an upper surface of the display module DM (see FIG. 6), and an upper surface of the first layer L1 may be in direct contact with a lower surface of the hard coating layer HC.

The first layer L1 may include a resin material which is cured by laser irradiation. In an embodiment, for example, the first layer L1 may be formed by applying and curing a resin material such as a resin. Alternatively, the first layer L1 may include a polyethylene terephthalate (PET) film. The first layer L1 may be referred to as a “resin layer”.

In an embodiment, when the first layer L1 includes the resin material which is cured by laser irradiation, a lamination process may be omitted during the manufacturing of a display device, thereby simplifying a display device manufacturing process and reducing costs.

In the window WM-3 according to an embodiment, the first layer L1 may have a greater thickness than the hard coating layer HC. In an embodiment, for example, the first layer L1 may have a thickness of about 250 μm to about 350 μm. In an embodiment, the first layer L1 may have a thickness of about 300 μm. Additionally, the hard coating layer HC may have a thickness of about 10 μm to about 15 μm. When the first layer L1 and the hard coating layer HC of the window WM-3 may have the above-described thickness ranges, respectively, the window WM-3 according to an embodiment may exhibit excellent durability.

The window WM-3 according to an embodiment may further include, on the hard coating layer HC, a high refractive layer, a low refractive layer, and a functional layer. The high refractive layer, the low refractive layer, and the functional layer may be sequentially disposed on the hard coating layer HC. The contents of the high refractive layer HR, the low refractive layer LR, and the functional layer AF, which have been described with reference to FIG. 9, may be similarly applied to the high refractive layer, the low refractive layer, and the functional layer disposed on the hard coating layer HC in the window WM-3 according to an embodiment.

Hereinafter, with reference to Examples and Comparative Examples, a window according to an embodiment and a display device including the same will be described in more detail. However, the following Examples and Comparative Examples are merely one example for the more detailed description of the invention, and an embodiment of the invention is not limited to the following Examples and Comparative Examples.

### Examples

### 1. Manufacture and Evaluation of Window

### (Manufacture of Example 1)

A window having the stacked structure illustrated in FIG. 8 was manufactured. The window of Example 1 includes a hard coating layer formed by using a first resin composition according to an embodiment. That is, the window of this Example includes an adhesive layer and a hard coating layer which are sequentially stacked, the hard coating layer including a polymer formed from the first resin composition. The hard coating layer included in the window of Example 1 was formed by using the first resin composition including a photoinitiator, a fluorine-based compound, an acrylate-based compound, a reactive diluent, and an additive (highly flexible material).

### (Manufacture of Example 2)

A window having the stacked structure illustrated in FIG. 8 was manufactured. The window of Example 2 includes a hard coating layer formed by using a first resin composition according to an embodiment. That is, the window of Example includes an adhesive layer and a hard coating layer including a polymer formed from the first resin composition, which are sequentially stacked. The hard coating layer included in the window of Example 2 was formed by using the first resin composition which includes a photoinitiator, a fluorine-based compound, an acrylate-based compound, a reactive diluent, and an additive (highly flexible material) and further includes an ultraviolet absorber.

### (Manufacture of Comparative Example 1)

The window of Comparative Example 1 differs from the window of Example 1 in that a hard coating layer is not included.

### 2. Evaluation 1 of Window

The wear resistance, chemical resistance, etc., were measured to evaluate the windows according to Example 1 and Comparative Example 1. Respective evaluation methods are as follows.

### (1) Wear Resistance

The wear resistance may also be referred to as eraser wear resistance. The wear resistance was evaluated by observing, with the naked eyes, a surface on which a wear test was carried out with an eraser or by measuring a water contact angle of the surface.

The window to be evaluated was cut into pieces of about 7 centimeters (cm) x about 8 cm and fixed to a wear resistance tester (scratch tester made by Daesung Precision Co.) jig, and an eraser (rubber stick made by Minoan Inc.) having a diameter of about 6 millimeters (mm) was attached and fixed to the tip thereof. A moving distance of about 15 mm, a moving speed of about 50 revolutions per minute (rpm), and a load of about 1.0 kilogram (kg) were set, and the eraser was reciprocally rubbed against a surface of the test window. Thereafter, the surface was observed with the naked eyes, or a water contact angle of the surface which was worn after reciprocally rubbed was measured according to the water contact angle measurement method described above.

### (2) Chemical Resistance

The chemical resistance may also be referred to as eraser chemical wear resistance. The chemical resistance was evaluated by providing chemicals to a surface of the window, and then observing, with the naked eyes, the surface worn with an eraser or measuring a water contact angle of the surface.

The window to be evaluated was cut into pieces of about 7 cm x about 8 cm and fixed to a wear resistance tester (scratch tester made by Daesung Precision Co.) jig, and an eraser (rubber stick made by Minoan Inc.) having a diameter of about 6 mm was attached and fixed to the tip thereof. An anhydrous ethanol was sprayed on the surface of the test window, and then a moving distance of about 15 mm, a moving speed of about 50 rpm, and a load of about 1.0 kg were set in the presence of ethanol. Thereafter, an eraser was reciprocally rubbed against the surface of the test window, and then the surface was observed with the naked eyes, or a water contact angle of the surface which was worn after reciprocally rubbed and wiped several times was measured according to the water contact angle measurement method described above.

TABLE 1

| | | Comparative | Example |
|---|---|---|---|
| Classification | | Example 1 | 1 |
| Wear | Number of times | 500 | 2000 |
| Resistance | Water Contact Angle | <95° | ≥95° |
| Chemical | Number of times | 500 | 2000 |
| Resistance | Water Contact Angle(°) | <95° | ≥95° |

Referring to Table 1, it may be confirmed that compared to Comparative Example 1, the window of Example 1 maintains a water contact angle of about 95° or more even after evaluating the wear resistance and chemical resistance, and exhibits excellent wear resistance and chemical resistance. Additionally, it was observed that in the wear resistance and chemical resistance test, the surface of the window of Comparative Example 1, was damaged after the surface was reciprocally rubbed about 500 times. The window of Example 1 exhibited favorable surface characteristics even after the surface was reciprocally rubbed about 2000 times and about 1000 times. Compared to Comparative Example 1, the window of Example 1 includes the hard coating layer formed from the first resin composition, and thus exhibits excellent chemical resistance. That is, it may be confirmed that the window of the Example 1 exhibits an excellent mechanical property and durability, compared to Comparative Example 1.

Additionally, compared to Comparative Example 1, the window of Example 1 may exhibit excellent durability even when the hard coating layer is not included. The window of Example 1 may include a high refractive layer formed from the first resin composition containing a highly flexible material, thereby not only having a hard coating function, but also exhibiting a high refractive index characteristic. Therefore, when the window of Example 1 is applied to a display device, it is possible to not only ensure excellent durability, but also reduce the overall thickness of the display device.

### 3. Light Transmittance Measurement

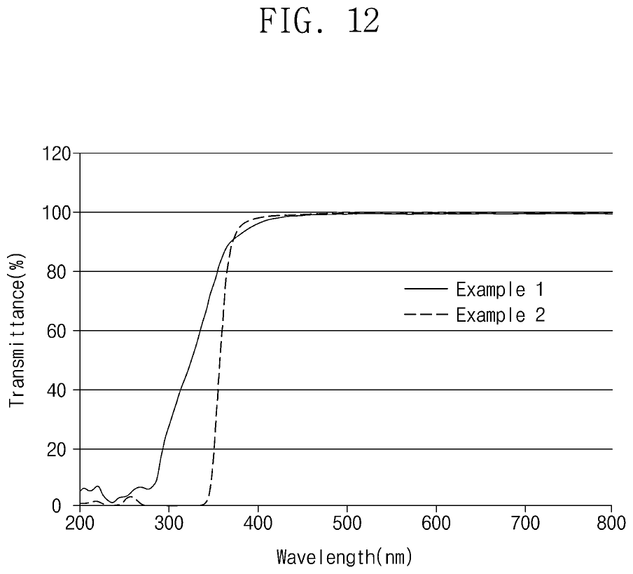

FIG. 12 is a graph showing a light transmittance of a window according to embodiments of the invention. Specifically, FIG. 12 shows evaluation results of optical properties of the windows of Example 1 and Example 2. Referring to FIG. 12, it may be confirmed that the window, of Example 2, which includes a hard coating layer formed from a first resin composition further including an ultraviolet absorber blocks most of ultraviolet rays with a wavelength of about 350 nm or less. That is, the window of Example 2 exhibited an excellent UV blocking property, compared to Example 1. Therefore, when the window including the hard coating layer containing an ultraviolet absorber is applied to a display device, it may be possible to provide a display device with improved visibility.

A window according to embodiments of the invention includes a hard coating layer containing certain components, thereby exhibiting excellent wear resistance and chemical resistance and having an excellent folding property to prevent cracks.

Therefore, a display device including the window described above exhibits excellent durability even in a low curvature structure, thereby providing an improved visibility.

Although the embodiments of the invention have been described, it is understood that the invention should not be limited to these embodiments but various changes and modifications can be made by one ordinary skilled in the art within the spirit and scope of the invention as hereinafter claimed.

Therefore, the technical scope of the invention is not limited to the contents described in the detailed description of the specification, but should be determined by the claims.

What is claimed is:

1. A window comprising a hard coating layer including a polymer derived from a resin composition including a photoinitiator, a fluorine-based compound, an acrylate-based compound, and a reactive diluent,
wherein the acrylate-based compound includes at least one of polyester acrylate, epoxy acrylate, urethane acrylate, or ethylene glycol acrylate, and
the reactive diluent includes at least one of polyester acrylate or polyether acrylate having a molecular weight of greater than 0 grams per mole (g/mol) and about 1000 grams per mole (g/mol) or less.

2. The window of claim 1, wherein the resin composition further includes an ultraviolet absorber, and
the ultraviolet absorber includes at least one of a salicylic acid-based compound, a benzophenone-based compound, a benzotriazole-based compound, a cyanoacrylate-based compound, a nickel phenolate-based compound, or a hindered amine-based compound.

3. The window of claim 2, wherein the ultraviolet absorber includes at least one of 2-(2-hydroxy-5-methylphenyl)benzotriazole, 2-(3-ter-butyl-2-hydroxy-5-methylphenyl)-2H-5-chlorobenzotriazole, 2-(2′-hydroxy-5′-ter-octylphenyl)benzotriazole, or 2-hydroxy-4-n-octoxybenzophenone.

4. The window of claim 1, further comprising:
an adhesive layer disposed below the hard coating layer; and
a primer layer disposed between the adhesive layer and the hard coating layer,
wherein the primer layer includes a silicon oxide and an ultraviolet absorber, and
the ultraviolet absorber includes at least one of a salicylic acid-based compound, a benzophenone-based compound, a benzotriazole-based compound, a cyanoacrylate-based compound, a nickel phenolate-based compound, or a hindered amine-based compound.

5. The window of claim 1, wherein the photoinitiator comprises at least one of an acetophenone-based compound, a sulfonium-based compound, or a benzophenone-based compound.

6. The window of claim 1, wherein the fluorine-based compound comprises perfluoropolyether.

7. The window of claim 1, wherein the resin composition further includes an additive represented by Chemical Formula 1 or Chemical Formula 2: 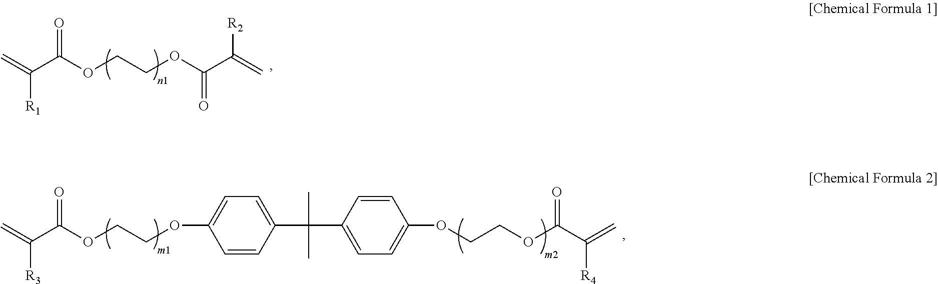
wherein in Chemical Formula 1 and Chemical Formula 2,
R₁ to R₄ is each independently a hydrogen atom or an unsubstituted methyl group,
n1 is an integer of 1 to 10,
m1 and m2 are each independently an integer of 1 to 20, and
a sum of m1 and m2 is 10 to 30.

8. The window of claim 1, wherein the acrylate-based compound further includes alkyl (meth)acrylate.

9. The window of claim 1, further comprising:
a high refractive layer disposed on the hard coating layer and having a first refractive index of about 1.6 or more; and
a low refractive layer disposed on the high refractive layer and having a second refractive index of about 1.5 or less.

10. The window of claim 9, wherein the high refractive layer comprises at least one of tin oxide (SnOₓ), titanium oxide (TiOₓ), zirconium oxide (ZrOₓ), or a sulfur atom.

11. The window of claim 9, wherein the low refractive layer comprises hollow particles having an average diameter of about 30 nanometers (nm) to about 70 nm.

12. The window of claim 9, further comprising a functional layer disposed on the low refractive layer and including a fluorine-containing compound.

13. The window of claim 1, wherein the hard coating layer has a thickness of about 10 micrometers (μm) to about 100 μm.

14. A display device comprising:
a display panel; and
a window disposed on the display panel,
wherein the window comprises a hard coating layer including a polymer derived from a resin composition including a photoinitiator, a fluorine-based compound, an acrylate-based compound, and a reactive diluent,
the acrylate-based compound includes at least one of polyester acrylate, epoxy acrylate, urethane acrylate, or ethylene glycol acrylate, and
the reactive diluent includes at least one of polyester acrylate or polyether acrylate having a molecular weight of greater than 0 g/mol and about 1000 g/mol or less.

15. The display device of claim 14, wherein the window further comprises:
an adhesive layer disposed below the hard coating layer and being in direct contact with an upper surface of the display panel;
a high refractive layer disposed on the hard coating layer;
a low refractive layer disposed on the high refractive layer and having a refractive index lower than a refractive index of the high refractive layer; and
a functional layer disposed on the low refractive layer and including a fluorine-containing compound.

16. The display device of claim 15, wherein the adhesive layer has a thickness of about 10 μm to about 100 μm, and
the hard coating layer has a thickness of about 50 μm to about 100 μm.

17. The display device of claim 14, wherein the resin composition further includes an ultraviolet absorber which blocks ultraviolet rays having a wavelength of about 350 nm or less.

18. The display device of claim 14, further comprising an optical layer disposed between the display panel and the window,
wherein the window further comprises a resin layer disposed below the hard coating layer and being in direct contact with the optical layer, and
the resin layer includes a polyethylene terephthalate (PET) film or a resin material cured by laser irradiation.

19. The display device of claim 18, wherein the hard coating layer has a thickness of about 10 μm to about 15 μm.

20. A display device comprising:
a display module including a first non-folding region, a folding region, and a second non-folding region, which are disposed along a first direction; and
a window disposed on the display module,
wherein the window includes
an adhesive layer directly disposed on the display module, and
a hard coating layer disposed on the adhesive layer and including a polymer derived from a resin composition including a photoinitiator, a fluorine-based compound, an acrylate-based compound, a reactive diluent, and an ultraviolet absorber, and
wherein the reactive diluent includes at least one of polyester acrylate or polyether acrylate having a molecular weight of greater than 0 g/mol and about 1000 g/mol or less.
